(19) United States
(12) Patent Application Publication
(10) Pub. No.: US 2026/0321961 A1
(43) Pub. Date: Oct. 15, 2026

(54) FLEXIBLE ANTENNA-IN-PACKAGE STRUCTURE

(71) Applicant: POWERTECH TECHNOLOGY INC., Hsinchu County (TW)

(72) Inventor: CHING LUNG CHIANG, Hsinchu County (TW)

(21) Appl. No.: 19/578,926

(22) Filed: Mar. 26, 2026

(30) Foreign Application Priority Data
Apr. 10, 2025 (TW) 114113485

(51) Int. Cl. H01Q 1/22; H10W 70/67; H10W 74/10

(52) U.S. Cl. CPC H01Q 1/2283; H10W 70/688; H10W 74/121

(57) ABSTRACT

A flexible antenna-in-package structure includes a substrate film, an antenna structure and a package body. The antenna structure is disposed in a first region of the substrate film. The package body is disposed in a second region of the substrate film, and a first surface of the package body is electrically connected to the substrate film. The first region of the substrate film is bent toward a second surface of the package body, so that the antenna structure is overlapped on the second surface, and the antenna structure is electrically connected to the package body through the second region and the first surface.

### RELATED APPLICATIONS

This application claims priority to Taiwan Application Serial Number 114113485, filed Apr. 10, 2025, which are herein incorporated by references.

### BACKGROUND

### Technical Field

The present disclosure relates to an antenna-in-package (AiP) structure. More particularly, the present disclosure relates to a flexible antenna-in-package structure.

### Description of Related Art

The internet of things (IoT) era has arrived, and a variety of electronic products can be controlled and fed back state thereof via the internet. Further, a signal transmission requires an antenna, and the antenna is becoming minimized along with higher of transmission frequencies. However, the conventional technology requires an additional fabrication of the antenna, and the cost thereof is too high and the product volume is too large. Therefore, a flexible antenna-in-package structure, which is low-cost and miniaturized, needs to be developed.

### SUMMARY

According to one aspect of the present disclosure, a flexible antenna-in-package structure includes a substrate film, an antenna structure and a package body. The antenna structure is disposed in a first region of the substrate film. The package body is disposed in a second region of the substrate film, and a first surface of the package body is electrically connected to the substrate film. The first region of the substrate film is bent toward a second surface of the package body, so that the antenna structure is overlapped on the second surface, and the antenna structure is electrically connected to the package body through the second region and the first surface.

According to one aspect of the present disclosure, a flexible antenna-in-package structure includes a substrate film, an antenna structure and a package body. The substrate film is curved, and includes a first section and a second section. The antenna structure is disposed in the first section. The package body is disposed between the first section and the second section, and a first surface of the package body is electrically connected to the second section. The antenna structure is overlapped on a second surface of the package body, and the antenna structure is electrically connected to the package body through the second section and the first surface.

### BRIEF DESCRIPTION OF THE DRAWINGS

FIG. 1 is a schematic view of a flexible antenna-in-package structure according to the 1st example of the present disclosure.

FIG. 2 is a schematic view of a flexible antenna-in-package structure according to the 2nd example of the present disclosure.

FIG. 3 is a schematic view of a flexible antenna-in-package structure according to the 3rd example of the present disclosure.

FIG. 4 is a schematic view of chips, which are stacked on each other, of the flexible antenna-in-package structure according to the present disclosure.

FIG. 5 is a schematic view of chips, which are disposed at intervals from each other, of the flexible antenna-in-package structure according to the present disclosure.

FIG. 6 is another schematic view of chips, which are disposed at intervals from each other, of the flexible antenna-in-package structure according to the present disclosure.

### DETAILED DESCRIPTION

A plurality of examples of the present disclosure will be described with the drawings. For clarity, some practical details will be described below. However, it should be noted that the present disclosure should not be limited by the practical details, that is, in some examples, the practical details is unnecessary. In addition, directional terms used herein (for example, up, down, left, right, top, bottom, X direction, Y direction, Z direction) are only used to be references to the drawings and not intended to imply absolute orientation. For simplifying the drawings, some conventional structures and elements will be simply illustrated, and repeated elements may be represented by the same labels.

Further, it will be understood that when an element is referred to as be “connected to” another element, it can be directly connected to other element, or it can be indirectly connected to the other element, that is, intervening elements may be present. In contrast, when an element is referred to as be “directly connected to” another element, there are no intervening elements present. In addition, the terms first, second, third, etc. are used herein to describe various elements or components, these elements or components should not be limited by these terms. Consequently, a first element or component discussed below could be termed a second element or component.

An AiP technology is to integrate one or multiple antennas and a front-end radio frequency circuit into a complete transceiver module. Further, a fifth-generation (5G) millimeter wave band has a sufficient bandwidth to create the next-generation communication foundation for the better user experience and the industrial application development. Hence, the AiP technology will be a key factor of the development of the 5G millimeter wave band, and the present disclosure is to integrate an antenna into an integrated circuit (IC) package so as to significantly save the space. Moreover, a miniaturized antenna-in-package structure of the present disclosure can increase a receiving sensitivity thereof by an array type, and a volume of components can be more saved by a structure integrated with a package body, thereby achieving effective resource utilization.

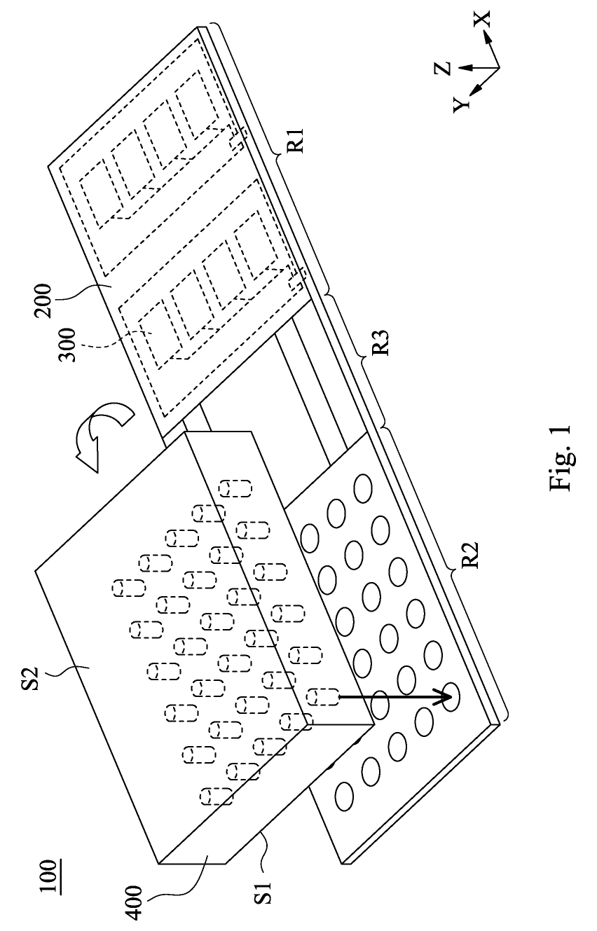

Please refer to FIG. 1, FIG. 1 is a schematic view of a flexible antenna-in-package structure 100 according to the 1st example of the present disclosure. The flexible antenna-in-package structure 100 includes a substrate film 200, an antenna structure 300 and a package body 400. The antenna structure 300 is disposed in a first region R1 of the substrate film 200. The package body 400 is disposed in a second region R2 of the substrate film 200, and a first surface S1 of the package body 400 is electrically connected to the substrate film 200. The substrate film 200 is originally planar (a flat surface in directions X, Y). The first region R1 of the substrate film 200 is bent toward a second surface S2 of the package body 400, so that the antenna structure 300 is overlapped on the second surface S2, and the antenna structure 300 is electrically connected to the package body 400 through the second region R2 and the first surface S1.

In particular, the first region R1 of the substrate film 200 is first bent toward a direction Z (a positive Z direction) and then bent toward the direction X (a negative X direction), so that the first region R1 is attached to the second surface S2 of the package body 400. The substrate film 200 has a third region R3 located between the first region R1 and the second region R2, and a metal connecting wire is disposed in the third region R3. The antenna structure 300 located in the first region R1 is electrically connected to the package body 400 through the third region R3 of the substrate film 200, the second region R2 of the substrate film 200 and the first surface S1; in other words, the antenna structure 300 located in the first region R1 can be electrically connected to a component (such as a pad) located in the second region R2 via the metal connecting wire located in the third region R3, and the component located in the second region R2 is electrically connected to the package body 400 by a flip chip bond or a wire bond. The antenna structure 300 can include a corresponding pattern according to the required frequency band. In an example, the antenna structure 300 is disposed inside the substrate film 200 (that is, embedded inside the substrate film 200); the package body 400 can include at least one chip and a molding, or can be the chip itself, but the present disclosure is not limited thereto.

Hence, the flexible antenna-in-package structure 100 of the present disclosure is to dispose the antenna structure 300 in the substrate film 200, connect the package body 400 to the substrate film 200, and then bend the substrate film 200 to above the package body 400 to fix. Therefore, the transceiver function of the antenna can be achieved, the manufacturing cost can also be saved, and the compact size can be achieved.

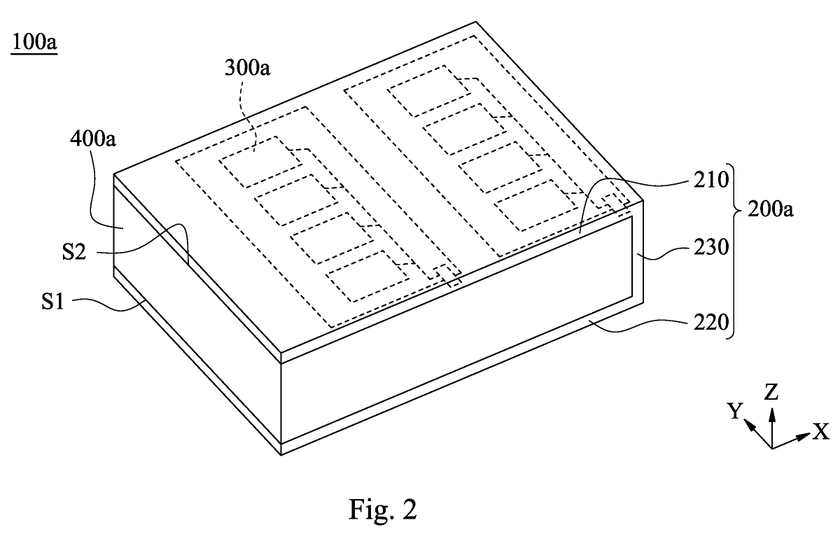

Please refer to FIGS. 1 and 2, wherein FIG. 2 is a schematic view of a flexible antenna-in-package structure 100a according to the 2nd example of the present disclosure. The flexible antenna-in-package structure 100a includes a substrate film 200a, an antenna structure 300a and a package body 400a. The substrate film 200a is curved, and includes a first section 210 and a second section 220. The antenna structure 300a is disposed in the first section 210. The package body 400a is disposed between the first section 210 and the second section 220, and a first surface S1 of the package body 400a is electrically connected to the second section 220. The antenna structure 300a is overlapped on a second surface S2 of the package body 400a, and the antenna structure 300a is electrically connected to the package body 400a through the second section 220 and the first surface S1.

In particular, the first section 210 of the substrate film 200a is attached to the second surface S2 of the package body 400a. The substrate film 200a further includes a third section 230. The first section 210, the second section 220 and the third section 230 are located in the first region R1, the second region R2 and the third region R3, respectively. The substrate film 200a is the structure of the substrate film 200 in FIG. 1 after bending, and a shape thereof is corresponding to a shape of a top, a lateral and a bottom of the package body 400a (such as an inverted C-shape). Structures of the antenna structure 300a and the package body 400a are the same as structures of the antenna structure 300 and the package body 400 in FIG. 1, respectively.

Therefore, the flexible antenna-in-package structure 100a of the present disclosure can integrate the antenna structure 300a with the package body 400a. Further, an additional fabrication of an antenna can be eliminated by a structure of AiP, and a functional integration of the package body 400a can be enhanced. Moreover, the antenna structure 300a which is miniaturized can increase the receiving sensitivity thereof by an array type, and an integrated structure of the antenna structure 300a and the package body 400a can further save the volume of components.

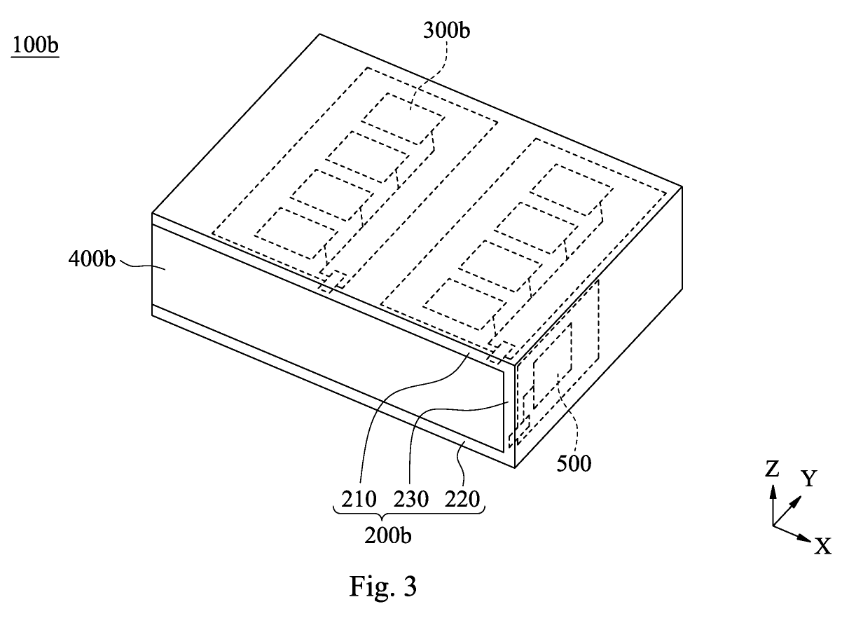

Please refer to FIGS. 2 and 3, wherein FIG. 3 is a schematic view of a flexible antenna-in-package structure 100b according to the 3rd example of the present disclosure. The flexible antenna-in-package structure 100b includes a substrate film 200b, an antenna structure 300b, a package body 400b and another antenna structure 500, wherein structures of the substrate film 200b, the antenna structure 300b and the package body 400b are the same as structures of the substrate film 200a, the antenna structure 300a and the package body 400a in FIG. 2, respectively. The flexible antenna-in-package structure 100b in FIG. 3 further includes the antenna structure 500 disposed in a third section 230 of the substrate film 200b, and electrically connected to the package body 400b. The antenna structures 300b, 500 face toward directions Z, X, respectively. The third section 230 is corresponding to a side of the package body 400b, and connected between the first section 210 and the second section 220. The antenna structure 500 is electrically connected to the package body 400b through the second section 220 and the first surface S1. Therefore, the flexible antenna-in-package structure 100b of the present disclosure is to utilize the antenna structure 500 to cover more antenna frequency bands so as to adapt to various application requirements of frequency bands.

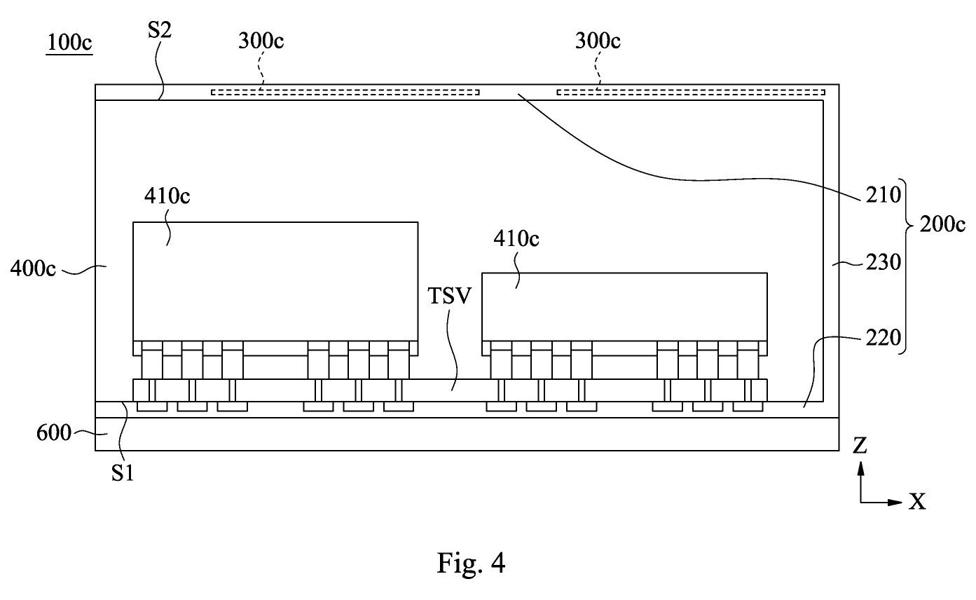

Please refer to FIGS. 2 and 4, wherein FIG. 4 is a schematic view of chips 410c, which are stacked on each other, of the flexible antenna-in-package structure 100c according to the present disclosure. The flexible antenna-in-package structure 100c includes a substrate film 200c, an antenna structure 300c, a package body 400c and an electronic element 600, wherein structures of the substrate film 200c and the antenna structure 300c are the same as structures of the substrate film 200a and the antenna structure 300a in FIG. 2, respectively. The package body 400c in FIG. 4 includes a plurality of chips 410c. Each of the chips 410c and a through-silicon via TSV are stacked on each other, and is electrically connected to the second section 220 of the substrate film 200c through the through-silicon via TSV. The second surface S2 of the package body 400c is a flat surface. Further, the flexible antenna-in-package structure 100c in FIG. 4 further includes the electronic element 600 connected to the second section 220 of the substrate film 200c, so that the second section 220 of the substrate film 200c is located between the package body 400c and the electronic element 600. In an example, the electronic element 600 can be another package body, and the chips 410c can obtain the same function or the different functions according to the requirements of actual application, and the present disclosure is not limited thereto. For example, the chips 410c can be logic chips, memory chips or a combination thereof. The through-silicon via TSV can be a bridge chip that bridges the chips 410c to each other and electrically connected to the second section 220 of the substrate film 200c. Therefore, the flexible antenna-in-package structure 100c of the present disclosure is favorable for increasing the signal processing capability and the scalability by stacking multiple chips 410c.

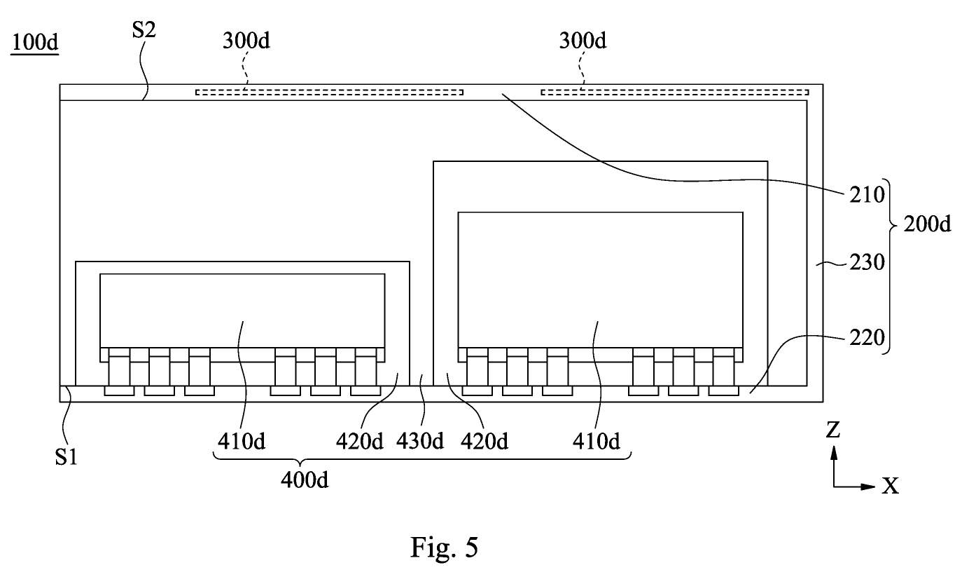

Please refer to FIGS. 2 and 5, wherein FIG. 5 is a schematic view of chips 410d, which are disposed at intervals from each other, of the flexible antenna-in-package structure 100d according to the present disclosure. The flexible antenna-in-package structure 100d includes a substrate film 200d, an antenna structure 300d and a package body 400d, wherein structures of the substrate film 200d and the antenna structure 300d are the same as the structures of the substrate film 200a and the antenna structure 300a in FIG. 2, respectively. The package body 400d in FIG. 5 includes a plurality of chips 410d, a plurality of first moldings 420d and a second molding 430d. The chips 410d are disposed at intervals from each other, and electrically connected to the second section 220 of the substrate film 200d. The first moldings 420d cover the chips 410d, respectively. The second molding 430d covers the first moldings 420d. The number of the chips 410d is equal to the number of the first moldings 420d. All of the first moldings 420d and the second molding 430d are molding materials. In an example, both of the number of the chips 410d and the number of the first moldings 420d are two, and the chips 410d can obtain the same function or the different functions according to the requirements of actual application, and the present disclosure is not limited thereto. For example, the chips 410d can be the logic chips, the memory chips or the combination thereof. Therefore, the flexible antenna-in-package structure 100d of the present disclosure is to integrate two packages (each package includes one first molding 420d and one chip 410d corresponding thereto) via three molding interfaces (that is two first moldings 420d and one second molding 430d), so that the signal processing capability and the scalability can be promoted.

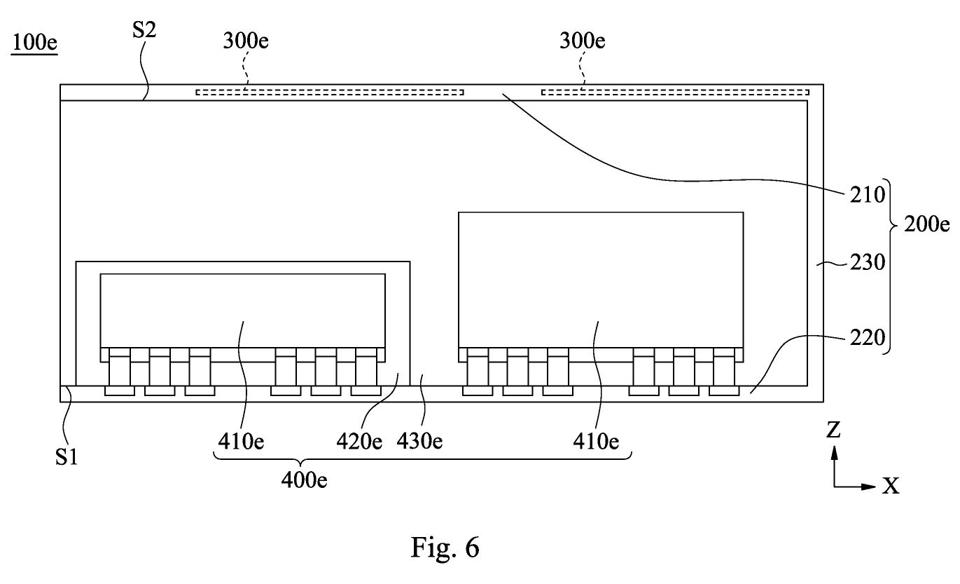

Please refer to FIGS. 5 and 6, wherein FIG. 6 is another schematic view of chips 410e, which are disposed at intervals from each other, of the flexible antenna-in-package structure 100e according to the present disclosure. The flexible antenna-in-package structure 100e includes a substrate film 200e, an antenna structure 300e and a package body 400e, wherein structures of the substrate film 200e and the antenna structure 300e are the same as the structures of the substrate film 200d and the antenna structure 300d in FIG. 5, respectively. The package body 400e in FIG. 6 includes a plurality of chips 410e, a first molding 420e and a second molding 430e. The difference between the package body 400e in FIG. 6 and the package body 400d in FIG. 5 is that the chip 410e located on the right side of the package body 400e in FIG. 6 is covered via the second molding 430e rather than the first molding 420e. In other words, the second molding 430e covers the chip 410e located on the right side and the first molding 420e located on the left side. Therefore, the flexible antenna-in-package structure 100e of the present disclosure is to integrate two packages (the left package includes one first molding 420e and one chip 410e corresponding thereto, and the right package only includes one chip 410e) via two molding interfaces (that is one first molding 420e and one second molding 430e), so that the signal processing capability and the scalability can be promoted.

In an example, each of the aforementioned substrate films 200, 200a, 200b, 200c, 200d, 200e can be an integrated substrate. The aforementioned flexible antenna-in-package structures 100, 100a, 100b, 100c, 100d, 100e can be applied to the 5G millimeter wave band, but the present disclosure is not limited thereto.

According to the aforementioned examples, the flexible antenna-in-package structure of the present disclosure has the following advantages. First, the antenna structure is disposed in the substrate film, the package body is connected to the substrate film, and then the substrate film is bent to above the package body to fix, so that the transceiver function of the antenna can be achieved, and the manufacturing cost can be also saved and the compact size can be achieved so as to solve the problem of the high cost and the large product size of the conventional technology. Second, the antenna structure can be integrated with the package body, and the additional fabrication of the antenna can be eliminated via the AiP structure so as to enhance the functional integration of the package body. Further, the receiving sensitivity of the miniaturized antenna-in-package structure can be enhanced by the array type, and the volume of components can be more saved by the structure integrated with the package body.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A flexible antenna-in-package structure, comprising:
a substrate film;
an antenna structure disposed in a first region of the substrate film; and
a package body disposed in a second region of the substrate film, and a first surface of the package body electrically connected to the substrate film;
wherein the first region of the substrate film is bent toward a second surface of the package body, so that the antenna structure is overlapped on the second surface, and the antenna structure is electrically connected to the package body through the second region and the first surface.

2. The flexible antenna-in-package structure of claim 1, further comprising:
another antenna structure disposed in a third region of the substrate film, and electrically connected to the package body, and the third region corresponding to a side of the package body, and connected between the first region and the second region.

3. The flexible antenna-in-package structure of claim 1, wherein the first region of the substrate film is attached to the second surface of the package body.

4. The flexible antenna-in-package structure of claim 1, further comprising:
an electronic element connected to the second region of the substrate film, so that the second region of the substrate film is located between the package body and the electronic element.

5. The flexible antenna-in-package structure of claim 1, wherein the package body comprises:
a plurality of chips stacked on each other, and electrically connected to the second region of the substrate film;
wherein the second surface of the package body is a flat surface.

6. The flexible antenna-in-package structure of claim 1, wherein the package body comprises:
a plurality of chips disposed at intervals from each other, and electrically connected to the second region of the substrate film;
at least one first molding covering at least one of the chips; and
a second molding covering the at least one first molding.

7. A flexible antenna-in-package structure, comprising:
a substrate film being curved, and comprising a first section and a second section;
an antenna structure disposed in the first section; and
a package body disposed between the first section and the second section, and a first surface of the package body electrically connected to the second section;
wherein the antenna structure is overlapped on a second surface of the package body, and the antenna structure is electrically connected to the package body through the second section and the first surface.

8. The flexible antenna-in-package structure of claim 7, further comprising:
another antenna structure disposed in a third section of the substrate film, and electrically connected to the package body, and the third section corresponding to a side of the package body, and connected between the first section and the second section.

9. The flexible antenna-in-package structure of claim 7, further comprising:
an electronic element connected to the second section of the substrate film, so that the second section of the substrate film is located between the package body and the electronic element.

10. The flexible antenna-in-package structure of claim 7, wherein the package body comprises:
a plurality of chips stacked on each other, and one of the chips electrically connected to the second section of the substrate film;
wherein the second surface of the package body is a flat surface.

11. The flexible antenna-in-package structure of claim 7, wherein the package body comprises:
a plurality of chips disposed at intervals from each other, and electrically connected to the second section of the substrate film;
at least one first molding covering at least one of the chips; and
a second molding covering the at least one first molding.
